(19) United States
(12) Patent Application Publication
(10) Pub. No.: US 2010/0237470 A1
(43) Pub. Date: Sep. 23, 2010

(54) EPITAXIAL WAFER

(75) Inventors: Kazushige Takaishi, Tokyo (JP); Tomonori Miura, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/740,426

(22) PCT Filed: Nov. 6, 2008
(86) PCT No.: PCT/JP2008/070237

§ 371 Date: Jun. 2, 2010

(30) Foreign Application Priority Data
Nov. 8, 2007 (JP) 2007-291340

(51) Int. Cl. H01L 29/30

(52) U.S. Cl. 257/618; 257/E29.106

(57) ABSTRACT

An epitaxial wafer is provided capable of eliminating particles in a device process, particles being generated from scratches in a boundary area between a rear surface and a chamfered surface of a wafer. The number of scratches in the boundary area between the rear surface and the chamfered surface is small, and thus the number of particles generated from the scratches is reduced at a time of immersion in an etching solution in the device process. Thereby, a device yield is increased.

### BACKGROUND OF THE INVENTION

1. Field of the Invention

The present invention relates to an epitaxial wafer, more specifically, an epitaxial wafer of which an epitaxial film is grown on a front surface in a vapor-phase epitaxial method in which a circular susceptor is used.

2. Description of Related Art

With increasing wafer diameter these days, a single-wafer type vapor-phase epitaxial growth apparatus is widely used, in order to grow an epitaxial film on a front surface of a silicon wafer. In a single-wafer type apparatus, a silicon wafer is first placed on a susceptor installed in a passageway-shaped reactor (chamber). Subsequently, when being heated by a heater provided external to the reactor, the silicon wafer is reacted with a variety of source gases (raw material gas and reactive gas), which pass through the reactor. Thereby, an epitaxial film is grown on a wafer front surface. A widely used susceptor has a circular shape from a plan view, on which a single wafer is mountable. The type of susceptor is used in order to evenly heat a wafer having a large diameter, such as, for example, a circular silicon wafer having a diameter of 300 mm, and to supply source gas on an entire wafer front surface; and thereby to evenly grow an epitaxial film. A wafer housing portion having a recess shape is provided in a middle portion of an upper surface of the susceptor, so as to house a silicon wafer having front and rear surfaces positioned horizontally. A recent susceptor generally supports a silicon wafer in a boundary area with a chamfered surface of a rear surface of the silicon wafer (for example, Related Art 1). In order to provide a wafer supporting position in the boundary area, one method is to evenly reduce a thickness of a middle portion of a bottom plate of the wafer housing portion, and thereby to provide a step around an external peripheral portion of the bottom plate. The other method is to cut out in a circular shape the middle portion of the bottom plate of the wafer housing portion, and thereby to provide the bottom plate having a ring shape. The boundary area means an area of less than 1 mm internally and externally in a direction of a wafer radius, centering a boundary line with the chamfered surface of the rear surface of the silicon wafer.

Silicon carbide (SiC) has conventionally been employed as material of a susceptor front surface. Thus, the susceptor has a greater hardness than the silicon wafer (Vickers hardness: SiC=2,200 to 2,500 HV; Si=1,050 HV). Further, the susceptor has a higher coefficient of thermal expansion than the silicon wafer, as the coefficient of thermal expansion of SiC is 4.8×10⁻⁶/k and that of silicon is 2.5×10⁻⁶/k. Thus, the boundary area of the wafer rear surface and an upper edge of an internal periphery of the external peripheral portion of the bottom plate of the wafer housing portion are in friction at a time of epitaxial growth, when a temperature inside the chamber is high. At the time, scratches are caused in the boundary area of the silicon wafer, which is softer than the susceptor. The scratch has a groove-like shape similar to a hangnail caused in a portion that rims a base of a nail (hangnail injury). A planar shape of the scratch is a line, a dot, and the like. A cross-sectional shape thereof is a V-shaped notch and the like.

Related Art 1: Japanese Patent Laid-open Publication No. 2003-229370

With microprocessing in a device process, however, problems described below occur when scratches exist on the rear surface of the silicon wafer in the boundary area between the chamfered surface and the wafer rear surface. Specifically, when the silicon wafer is immersed in an etching solution and the like in the device process, particles are generated from the scratched portion. The particles are deposited on the wafer front surface (device formed surface). Thus, a yield in the device process is reduced.

### SUMMARY OF THE INVENTION

The present invention provides an epitaxial wafer capable of preventing generation of particles caused by a scratch in a device process.

A first aspect of the invention provides an epitaxial wafer in which an epitaxial film is grown on a front surface of a semiconductor wafer in a vapor-phase epitaxial method, wherein the number of scratches in a boundary area with a chamfered surface of a rear surface of the semiconductor wafer is 5 or less, the scratches having a depth of 0.5 μm or greater and a length of 1 μm or greater.

According to the first aspect of the invention, the number of scratches in the boundary area with the chamfered surface of the rear surface of the semiconductor wafer is 5 or less, the scratches having the depth of 0.5 μm or greater and the length of 1 μm or greater. Thus, even when there is hypothetically a scratch, from which particles are generated at a time when the epitaxial wafer is immersed in treatment solutions, such as an etching solution and the like, in a subsequent device process, it is likely that all the particles are melted out in the etching solution and the like. Of course, when there is no scratch in the boundary area, no particles are generated from the boundary area. Accordingly, no particles move from the wafer rear surface side to the front surface side, and are deposited on the wafer front surface. Thus, a device yield can be increased.

A monocrystalline silicon wafer, a polycrystalline silicon wafer, and the like can be employed as the semiconductor wafer. A diameter of a silicon wafer may be determined as desired, such as, for example, 150 mm, 200 mm, or 300 mm or larger. Silicon same as the wafer (monocrystalline silicon and polycrystalline silicon) can be employed as material of the epitaxial film. Alternatively, material different from the wafer may be used, such as, for example, gallium, arsenic, and the like. A thickness of the epitaxial film is a few μm to 150 μm for bipolar devices and power devices, and 10 μm or less for MOS devices.

Examples of the vapor-phase epitaxial method may include an atmospheric vapor-phase epitaxial method, a reduced-pressure vapor-phase epitaxial method, an organic metal vapor-phase epitaxial method, and the like. In the vapor-phase epitaxial method, for example, a susceptor is used to house an epitaxial wafer laterally (a state in which front and rear surfaces are placed horizontally) in a wafer housing portion, the susceptor having a circular shape from a plan view and being mountable with a single wafer. When the wafer is housed, an upper edge of an internal periphery of an external peripheral portion of the wafer housing portion of the susceptor comes in contact (line contact) with the boundary area with the chambered surface of the rear surface of the epitaxial wafer. The annular contact line is a wafer supporting line. The boundary area with the chambered surface of the rear surface of the semiconductor wafer herein means a band-shaped area having a width of 1 mm internally and externally, a total of about 2 mm, in a direction of a wafer radius, centering a boundary line between the rear surface (flat surface) and the chamfered surface (curved surface) of the semiconductor wafer.

Silicon carbide, for instance, may be employed as material of a susceptor front surface. It is preferable to employ a material different from the semiconductor wafer for the material of the susceptor front surface. Thereby, the semiconductor wafer and the susceptor are prevented from melting and integrally adhering to each other due to heating at a time of epitaxial growth. Employing different materials for the semiconductor wafer and the susceptor results in different coefficients of thermal expansion.

The scratch herein is like a groove similar to a hangnail caused in a portion that rims a base of a nail (hangnail injury). A planar shape of the scratch is a line, a dot, and the like. A cross-sectional shape thereof is a V-shaped notch and the like. When a size of the scratch is less than 0.5 μm in depth and less than 1 μm in length, the number of particles is small even when particles are generated from the scratch at the time of immersion in an etching solution in the device process, and thus the particles are melted out in the etching solution. Thereby, it is unlikely that the particles move to the wafer front surface side and are deposited on the wafer front surface, and thus that the device yield is decreased due to the scratch. The size of frequently occurred scratches (hangnail injuries) on the wafer rear surface is 0.5 to 5 μm in depth and 5 to 100 μm in length. When the number of scratches exceeds 5, the number of particles deposited on the wafer front surface in the device manufacturing process is increased, and thus the device manufacturing yield is deteriorated. A preferable number of scratches is 3 or less. Within the range, the number of particles deposited on the wafer front surface in the device manufacturing process is reduced, and thus the device manufacturing yield is prevented from being deteriorated.

A second aspect of the invention provides the epitaxial wafer according to the first aspect, wherein the scratch has a groove shape similar to a hangnail caused in a portion that rims a base of a nail.

A third aspect of the invention provides the epitaxial wafer according to the first or second aspect, wherein the boundary area is an area of less than 1 mm internally and externally in a radius direction of the wafer, centering a boundary line with the chamfered surface of the rear surface of the silicon wafer. When the boundary area exceeds the area of less than 1 mm internally and externally in the wafer radius direction centering the boundary line with the chamfered surface of the rear surface of the silicon wafer, particles generated from a scratch existing in an area of 1 mm or greater externally in the wafer radius direction centering the boundary line with the chamfered surface are deposited on the wafer front surface in the device manufacturing process, thus deteriorating the device manufacturing yield.

According to the first aspect of the invention, the number of scratches in the boundary area with the chamfered surface of the rear surface of the semiconductor wafer is 5 or less, the scratches having the depth of 0.5 μm or greater and the length of 1 μm or greater. Thus, even when particles are generated from the scratches in the subsequent device process, it is unlikely that the particles move to the wafer front surface side and are deposited on the wafer front surface. Thereby, the device yield can be increased.

### BRIEF DESCRIPTION OF THE DRAWINGS

FIG. 1 is an enlarged vertical cross-sectional view of an epitaxial wafer according to a first embodiment of the present invention;

FIG. 2 is an enlarged cross-sectional view of a main portion of epitaxial growth of the epitaxial wafer according to the first embodiment of the present invention; and

FIG. 3 is an enlarged vertical cross-sectional view of a scratch on the epitaxial wafer according to the first embodiment of the present invention.
10 Epitaxial wafer
11 Silicon wafer (semiconductor wafer)
12 Epitaxial film
a Boundary area
b Scratch

### DETAILED DESCRIPTION OF PREFERRED EMBODIMENTS

The embodiment of the present invention is specifically explained below.

### First Embodiment

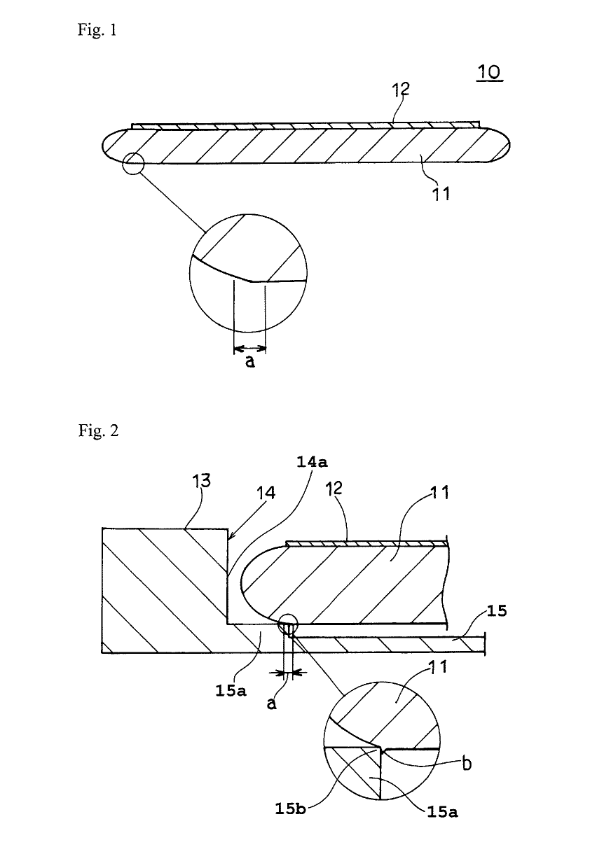

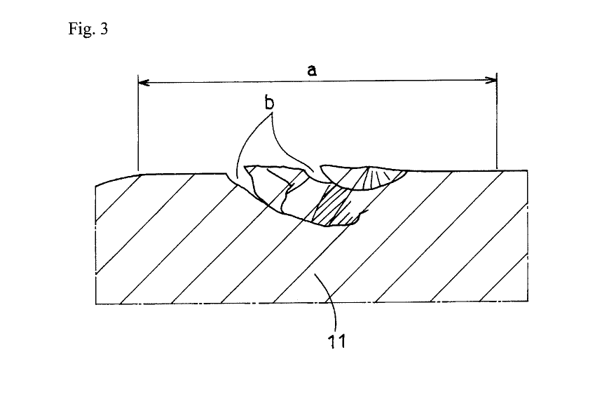

FIG. 1 shows an epitaxial wafer 10 according to the first embodiment of the present invention. The epitaxial wafer 10 has no scratch (cut scratch having a depth of 0.5 μm or greater and a length of 1 μm or greater) b in a boundary area a with a chamfered surface of a rear surface of a silicon wafer (semiconductor wafer) 11 (FIG. 2). In other words, a size of the scratch b existing in the boundary area a with the chamfered surface of the rear surface of the silicon wafer 11 is less than 0.5 μm in depth and less than 1 μm in length. The boundary area a herein is an area having a ring band shape of 0.1 mm inward and 0.1 mm outward in a radius direction of the wafer centering a boundary line having a perfect circle shape, the boundary line being formed as the rear surface (flat surface) and the chamfered surface (curved surface) of the silicon wafer 11 are contacted. The scratch b is shown in FIG. 3.

The epitaxial wafer 10 is explained in detail below. As shown in FIG. 1, the silicon wafer 11 is produced by pulling a monocrystalline silicon ingot from a silicon melt doped with a predetermined amount of boron in a crucible in the CZ process; slicing the ingot into a plurality of wafers by a wire saw; and chamfering each wafer by a chamfering apparatus, lapping by a lapping apparatus, etching by an etching apparatus, and polishing by a polisher, consecutively. Subsequently, an epitaxial film 12 is grown on a front surface of the silicon wafer 11 in a vapor-phase epitaxial method. The epitaxial film 12 is then simultaneously polished on both sides by a double-side polisher. Thereby, the epitaxial wafer is produced having merely a predetermined number (5) or less of scratches b in the boundary area a with the chamfered surface of the wafer rear surface. Other methods of removing the scratches b may include, for example, to etch the wafer rear surface; and, as shown in FIG. 2, to employ a bottom plate (wafer supporting plate) 15 having a longer radius for a wafer housing portion 14 of a susceptor 13, so as to change a supporting position of the epitaxial wafer 10 to a middle portion of the wafer.

An epitaxial growth process using a vapor-phase epitaxial growth apparatus is specifically explained below with reference to FIG. 2. As shown in FIG. 2, the vapor-phase epitaxial growth apparatus has the susceptor 13 provided horizontally in a middle portion of a chamber to which heaters are provided above and below (not shown in the drawing), the susceptor 13 having a circular shape from a plan view. Material of a front surface of the susceptor 13 is silicon carbide (Vickers hardness of 2,300 HV). The recess-shaped wafer housing portion 14 is provided in a middle portion of the front surface of the susceptor 13, so as to house the semiconductor wafer 11 in a state in which its front and rear surfaces are placed horizontally. The bottom plate 15 of the wafer housing portion 14 has a thin circular middle portion. Thereby, a step is provided having a boundary line at an upper edge of an internal periphery 15b of an external peripheral portion 15a of the bottom plate 15. The wafer housing portion 14 is demarcated by a peripheral wall 14a, the external peripheral portion (step portion) 15a having an annular shape from a plan view, and the bottom plate (bottom wall surface of the caved-in portion) 15. A pair of gas supply inlets are provided to a first side portion of the chamber to supply a predetermined carrier gas (H₂ gas) and a predetermined source gas (SiHCl₃ gas) to an upper space of the chamber, such that the gases flow in parallel to the wafer front surface. Further, a gas discharge outlet for the both gases is provided to a second side portion of the chamber.

At the time of epitaxial growth, the epitaxial wafer 10 is first placed in the wafer housing portion 14 of the susceptor 13, such that the front and rear surfaces of the wafer are provided horizontally. At the time, the upper edge of the internal periphery 15b of the external peripheral portion 15a of the bottom plate 15 comes in contact with the boundary area a with the chamfered surface of the rear surface of the epitaxial wafer 10. The contact is provided along an entire periphery of the epitaxial wafer 10. Subsequently, the carrier gas and the source gas are flown into the chamber from the respective gas supply inlets, and concurrently are heated, so as to hold a temperature inside the chamber at 1,100° C. to 1,200° C. Thereby, the epitaxial film 12 is grown on the front surface of the silicon wafer 11. A coefficient of thermal expansion is different between the semiconductor wafer 11 and the susceptor 13. Due to the difference, the boundary area a of the rear surface of the silicon wafer 11 is in friction with the upper edge of the internal periphery 15b of the external peripheral portion 15a of the bottom plate 15 at the time of heating in the epitaxial growth. Hardness of the front surface material of the susceptor 13 is greater at 2,300 HV than that of the silicon wafer 11. Thus, the scratches b are caused in the boundary area a between the chamfered surface and the wafer rear surface on the rear surface side of the wafer external peripheral portion, the scratches b being at the same level as on an epitaxial wafer manufactured in a conventional manufacturing method (hereinafter referred to as a conventional product). The size of the scratches b is 0.5 to 20 μm in depth and 1 to 500 μm in length.

Subsequently, the epitaxial wafer 10 is simultaneously polished on both sides by the double-side polisher. A polishing rate is higher for the wafer rear surface than for the wafer front surface (front surface of the epitaxial film 12). The different polishing rate is achieved by using a softer polishing cloth material for the wafer rear surface than a polishing cloth material for the wafer front surface. The special double-side polishing polishes and mirror-finishes the wafer front surface for 0.3 μm, and polishes the wafer rear surface for 0.5 μm. Thereby, the epitaxial wafer 10 having 5 or less scratches b in the boundary area a with the chamfered surface is produced. There is no problem as long as the size of the scratches b is less than 0.5 μm in depth and less than 1 μm in length. Within the size, even when particles are generated from the scratches b at a time of immersion in an etching solution in a device process, the number of particles is small, and thus all the particles are melted out in the etching solution. Thus, it is unlikely that the particles move to the wafer front surface side and are deposited on the wafer front surface.

The produced epitaxial wafer 10 is shipped to a device manufacturer, for instance, where devices are formed on the front surface of the epitaxial film 12. When the epitaxial wafer 10 is immersed in treatment solutions, such as an etching solution and the like, in the device process, the size and number of particles are small compared to a conventional product, even when particles are hypothetically generated from the scratches b caused by supporting of the susceptor 13. Thus, it is unlikely that the particles move to the wafer front surface side and are deposited on the wafer front surface, and that defects are caused in devices. Thereby, the device yield can be increased.

Test results are reported below in which occurrence of scratches is measured, with respect to the epitaxial wafer actually produced in the first embodiment (hereinafter referred to as a present invention product) and a conventional epitaxial wafer. Measured values are average values obtained in tests of 25 pieces, each of the epitaxial wafers of the first embodiment and the conventional epitaxial wafers. The number of scratches existing in the boundary area with the chamfered surface of the epitaxial wafer rear surface is counted (minimum measurement size: 0.2 μm) by using a detector of the wafer rear surface and end surface (manufactured by Raytex Corporation). As a result, for the present invention product, the number of scratches having a size of less than 0.5 μm in depth and less than 1 μm in length is 5, and the number of scratches having a size of 0.5 μm or greater in depth and 1 μm or greater in length is 0. For the conventional product, the number of scratches having a size of less than 0.5 μm in depth and less than 1 μm in length is 20, and the number of scratches having a size of 0.5 μm or greater in depth and 1 μm or greater in length is 40. The difference is thus clearly demonstrated.

The present invention is effective in manufacturing of epitaxial wafers to be used as substrates of MOS products, logic products, and the like.

1. An epitaxial wafer in which an epitaxial film is grown on a front surface of a semiconductor wafer in a vapor-phase epitaxial method, wherein the number of scratches in a boundary area with a chamfered surface of a rear surface of the semiconductor wafer is 5 or less, the scratches having a depth of 0.5 μm or greater and a length of 1 μm or greater.

2. The epitaxial wafer according to claim 1, wherein the scratch has a groove shape similar to a hangnail caused in a portion that rims a base of a nail.

3. The epitaxial wafer according to claim 1, wherein the boundary area is an area of less than 1 mm internally and externally in a radius direction of the wafer, centering a boundary line with the chamfered surface of the rear surface of the silicon wafer.

4. The epitaxial wafer according to claim 2, wherein the boundary area is an area of less than 1 mm internally and externally in a radius direction of the wafer, centering a boundary line with the chamfered surface of the rear surface of the silicon wafer.
